(19) United States
(12) Patent Application Publication
(10) Pub. No.: US 2013/0178022 A1
(43) Pub. Date: Jul. 11, 2013

(54) METHOD FOR FABRICATING TRANSISTOR WITH RECESSED CHANNEL AND RAISED SOURCE/DRAIN

(71) Applicants: Kangguo CHENG, Schenectady, NY (US); Ali KHAKIFIROOZ, Mountain View, CA (US); Sivananda KANAKASABAPATHY, Niskayuna, NY (US); Pranita KULKARNI, Slingerlands, NY (US); Balasubramanian S. HARAN, Watervliet, NY (US)

(72) Inventors: Kangguo CHENG, Schenectady, NY (US); Ali KHAKIFIROOZ, Mountain View, CA (US); Sivananda KANAKASABAPATHY, Niskayuna, NY (US); Pranita KULKARNI, Slingerlands, NY (US); Balasubramanian S. HARAN, Watervliet, NY (US)

(73) Assignee: INTERNATIONAL BUSINESS MACHINES CORPORATION, Armonk, NY (US)

(21) Appl. No.: 13/618,186

(22) Filed: Sep. 14, 2012

Related U.S. Application Data
(63) Continuation of application No. 13/347,161, filed on Jan. 10, 2012.

(51) Int. Cl. H01L 21/336

(52) U.S. Cl. 438/157; 257/E21.409

(57) ABSTRACT

A method is provided for fabricating a transistor. According to the method, a second semiconductor layer is formed on a first semiconductor layer, and a dummy gate structure is formed on the second semiconductor layer. A gate spacer is formed on sidewalls of the dummy gate structure, and the dummy gate structure is removed to form a cavity. The second semiconductor layer beneath the cavity is removed. A gate dielectric is formed on the first portion of the first semiconductor layer and adjacent to the sidewalls of the second semiconductor layer and sidewalls of the gate spacer. A gate conductor is formed on the first portion of the gate dielectric and abutting the second portion of the gate dielectric. Raised source/drain regions are formed in the second semiconductor layer, with at least part of the raised source/drain regions being below the gate spacer.

### CROSS-REFERENCE TO RELATED APPLICATIONS

This application is a continuation of prior U.S. application Ser. No. 13/347,161, filed Jan. 10, 2012, now U.S. Pat. No. ______. The entire disclosure of U.S. application Ser. No. 13/347,161 is herein incorporated by reference.

### FIELD OF THE INVENTION

The present invention generally relates to the field of semiconductors, and more particularly relates to field-effect transistors with a recessed channel and raised source/drain regions.

### BACKGROUND OF THE INVENTION

In order to increase the integration density of integrated circuits such as memory, logic, and other devices, the dimensions of field effect transistors (FETs) must be further downscaled. Scaling achieves compactness and improves operating performance in devices by shrinking the overall dimensions and operating voltages of the device while maintaining its electrical properties. All dimensions of the device must be scaled simultaneously in order to optimize the electrical performance of the device. With conventional planar FET scaling reaching fundamental limits, the semiconductor industry is looking to new geometries to facilitate continued device performance improvements.

### SUMMARY OF THE INVENTION

In one embodiment, a method for fabricating a transistor is disclosed. According to the method, a second semiconductor layer is formed on a first semiconductor layer, and a dummy gate structure is formed on the second semiconductor layer. After forming the dummy gate structure, a gate spacer is formed on vertical sidewalls of the dummy gate structure. After forming the gate spacer, the dummy gate structure is removed so as to form a cavity. The second semiconductor layer is removed beneath the cavity so as to expose a first portion of the first semiconductor layer and to create vertical sidewalls of the second semiconductor layer. A gate dielectric is formed comprising a first portion located on the first portion of the first semiconductor layer and a second portion adjacent to the vertical sidewalls of the second semiconductor layer and vertical sidewalls of the gate spacer. A gate conductor is formed on the first portion of the gate dielectric and abutting the second portion of the gate dielectric. Raised source/drain regions are formed in the second semiconductor layer, at least part of the raised source/drain regions being located below the gate spacer.

In another embodiment, a method for fabricating a fin-field-effect-transistor is disclosed. According to the method, a fin structure is provided atop a dielectric layer, and a semiconductor material is formed on sidewalls of the fin structure. A dummy gate structure is formed on the fin structure and the semiconductor material. After forming the dummy gate structure, a gate spacer is formed on vertical sidewalls of the dummy gate structure. After forming the gate spacer, the dummy gate structure is removed so as to form a cavity and an exposed portion of the fin structure in the cavity. After the cavity is formed, the semiconductor layer is removed from sidewalls of portion of the fin structure. A dielectric spacer is formed on the exposed portion of the fin structure. A gate conductor is formed within the cavity and over the dielectric spacer.

Other objects, features, and advantages of the present invention will become apparent from the following detailed description. It should be understood, however, that the detailed description and specific examples, while indicating various embodiments of the present invention, are given by way of illustration only and various modifications may naturally be performed without deviating from the present invention.

### BRIEF DESCRIPTION OF THE DRAWINGS

FIG. 1 shows a cross-sectional view of a semiconductor device comprising a substrate, buried insulator layer, and a first semiconductor layer according to a first embodiment of the present invention;

FIG. 2 shows a cross-sectional view of the semiconductor device after a second semiconductor layer has been formed on the first semiconductor layer according to the first embodiment of the present invention;

FIG. 3 shows a cross-sectional view of the semiconductor device after an active area has been formed with the first semiconductor layer according to the first embodiment of the present invention;

FIG. 4 shows a cross-sectional view of the semiconductor device after a dummy gate structure has been formed on the second semiconductor layer according to the first embodiment of the present invention;

FIG. 5 shows a cross-sectional view of the semiconductor device after a dielectric layer has been formed thereon according to the first embodiment of the present invention;

FIG. 6 shows a cross-sectional view of the semiconductor device after a the dummy gate structure has been removed so as to form a gate cavity according to the first embodiment of the present invention;

FIG. 7 shows a cross-sectional view of the semiconductor device after the second semiconductor layer has been selectively removed from the gate cavity according to the first embodiment of the present invention;

FIG. 8 shows a cross-sectional view of the semiconductor device after a dielectric layer and a gate conductor have been formed within the gate cavity according to the first embodiment of the present invention;

FIG. 9 shows a cross-sectional view of the semiconductor device after an additional dielectric layer has been formed within the gate cavity prior to forming the gate conductor according to the first embodiment of the present invention;

FIG. 10 shows a cross-sectional view of a semiconductor device after a fin structure has been formed thereon according to a second embodiment of the present invention;

FIG. 11 shows a cross-sectional view of a semiconductor device after a semiconductor layer has been formed on sidewalls of the fin structure and a dummy gate structure has been formed over a portion of the fin structure according to the second embodiment of the present invention;

FIG. 12 shows a cross-sectional view of a semiconductor device after the dummy gate structure has been removed so as to form a gate cavity and the semiconductor layer has been removed from sidewalls of the fin structure within the gate cavity according to the second embodiment of the present invention;

FIG. 13 shows another cross-sectional view of the semiconductor device of FIG. 12 after a dielectric layer has been removed according to the second embodiment of the present invention;

FIG. 14 shows a cross-sectional view of the semiconductor device after a gate conductor material has been formed over the fin structure within the gate cavity according to the second embodiment of the present invention;

FIG. 15 is an operational flow diagram illustrating processes for forming a transistor according to one embodiment of the present invention; and

FIG. 16 is another operational flow diagram illustrating another process for forming a transistor according to another embodiment of the present invention.

### DETAILED DESCRIPTION

Extremely thin silicon-on-insulator (ETSOI) technology has become a viable option for complementary metal-oxide-semiconductor (CMOS) applications. However, there are several challenges in fabricating ETSOI devices. First, the thin layer of silicon in the source/drain extension regions causes high external resistance. For this reason, raised source/drain regions are usually formed to lower this resistance. Raised source/drain regions are usually formed using epitaxial growth after gate patterning. However, the dependency of epitaxial growth on pitch causes variation in the thickness of raised source/drain regions in devices with different pitches. Another challenge is that the loss of material in the ETSOI layer during device fabrication (e.g., during etching) results in an inefficient silicon layer for epitaxially growing raised source/drain regions.

Embodiments of the present invention provide improved ETSOI devices and methods for forming such ETSOI devices. In one embodiment, an epitaxial (epi) layer is grown on top of the ETSOI layer, with the epitaxial layer being composed of a different material than the ETSOI (e.g., the ETSOI layer is silicon and the epitaxial layer is silicon-germanium). A dummy gate is formed on the epitaxial layer, and source/drain regions are formed in the epitaxial and ETSOI layers. The dummy gate is then removed to expose the epitaxial layer in the channel region. The exposed epitaxial layer is then selectively removed with respect to the ETSOI layer.

Good control of the ETSOI channel thickness is achieved by utilizing selective etching techniques. In addition, the ETSOI transistor only requires a single spacer and has a low resistance extension with a thick epitaxial layer. Further, raised source/drain regions are formed prior to gate patterning, which results in uniform raised source/drain regions across various pitches.

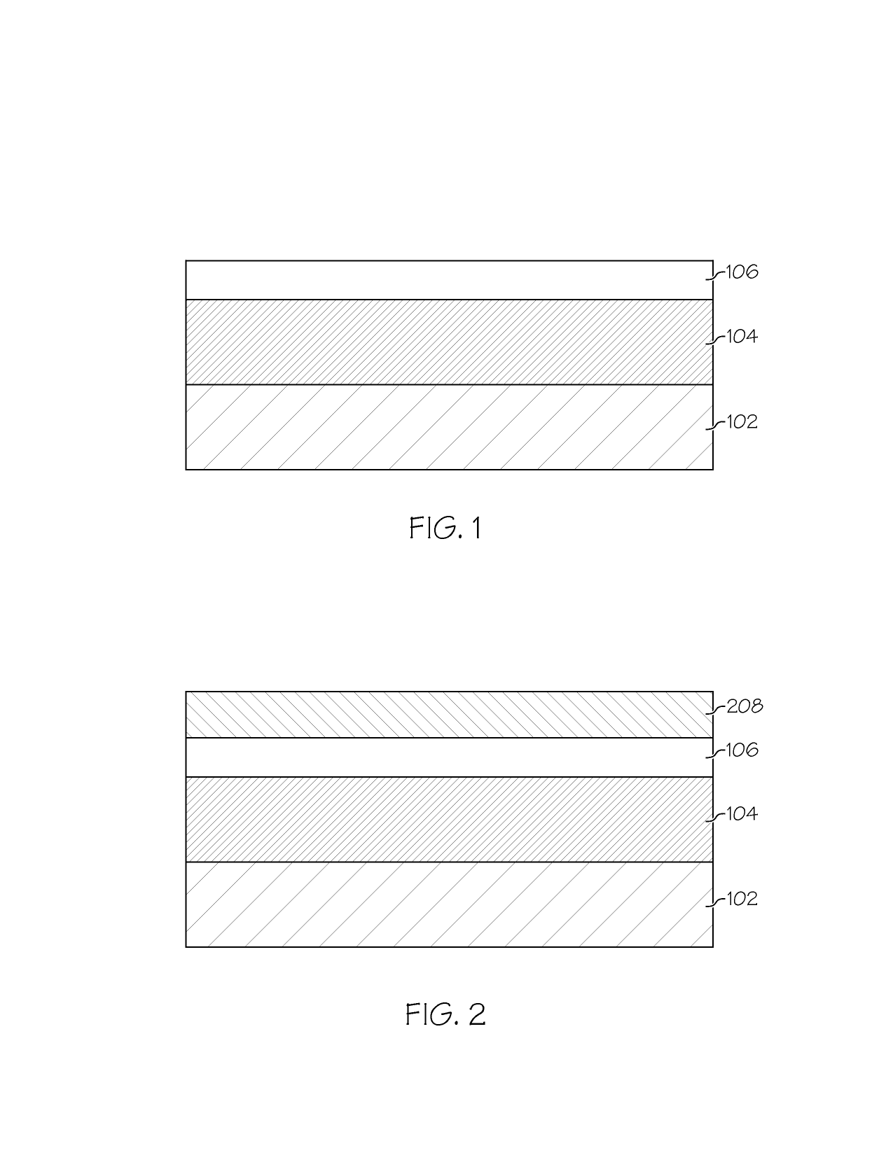

FIGS. 1 to 9 illustrate a process for forming an ETSOI transistor with a recessed channel and raised source/drain regions according to one embodiment of the present invention. As shown in FIG. 1, there is provided an SOI wafer having a silicon substrate 102, a buried oxide layer (BOX) 104, and an extremely thin silicon-on-insulator (ETSOI) layer 106 (“first semiconductor layer”). The ETSOI layer 106 of this embodiment has a thickness ranging from about 1 nm to 20 nm, while in another embodiment the ETSOI layer 106 has a thickness ranging from about 3 nm to 10 nm. In the illustrated embodiment, the SOI wafer is formed by thinning a “thick” SOI wafer with a thickness in the 30 nm to 90 nm range using oxidation and a hydrofluoric acid (HF) wet etch. The ETSOI layer 106 is any semiconducting material such as Si (silicon), strained Si, SiC (silicon carbide), SiGe (silicon germanium), SiGeC (silicon-germanium-carbon), Si alloys, Ge, Ge alloys, GaAs (gallium arsenide), InAs (indium arsenide), InP (indium phosphide), or any combination thereof.

As shown in FIG. 2, an additional semiconductor layer 208 (“second semiconductor layer”) is formed on exposed surfaces of the ETSOI layer 106. In this embodiment, the second semiconductor layer 208 is formed through epitaxial growth, and can be formed undoped or doped with either p-type or n-type dopants. The second semiconductor layer 208 provides the raised source and drain regions of the ETSOI device. When the chemical reactants are controlled and the system parameters set correctly, the depositing atoms arrive at the surface of the ETSOI layer 106 with sufficient energy to move around on the surface and orient themselves to the crystal arrangement of the atoms of the deposition surface. Thus, an epitaxial film deposited on a [100] crystal surface will take on a [100] orientation. If, on the other hand, the wafer has an amorphous surface layer, the depositing atoms have no surface to align to and form polysilicon instead of single crystal silicon. Silicon sources for the epitaxial growth include silicon tetrachloride, dichlorosilane (SiH2Cl2), and silane (SiH4). The temperature of this epitaxial silicon deposition is from 550° C. to 900° C.

In the illustrated embodiment, the second semiconductor layer 208 is formed through selective-epitaxial growth of SiGe atop the ETSOI layer 106. The Ge content of the epitaxial grown SiGe ranges from 5% to 60% (by atomic weight). In another embodiment, the Ge content of the epitaxial grown SiGe ranges from 10% to 40%. The epitaxially grown SiGe of the illustrated embodiment is under an intrinsic compressive strain that is produced by a lattice mismatch between the larger lattice dimension of the SiGe and the smaller lattice dimension of the layer on which the SiGe is epitaxially grown. The epitaxially grown SiGe produces a compressive strain in the portion of the ETSOI layer 106 in which the channel of a semiconductor device is subsequently formed.

In this embodiment, the second semiconductor layer 208 is doped with a first conductivity type dopant during the epitaxial growth process. P-type MOSFET devices are produced by doping the second semiconductor layer 208 with elements from group III of the periodic table (e.g., boron, aluminum, gallium, or indium). As an example, the dopant can be boron in a concentration ranging from 1×10E18 atoms/cm3 to 2×10E21 atoms/cm3. In this example, the second semiconductor layer 208 is composed of SiGe and is doped with boron to provide the raised source and drain regions of a P-channel field-effect transistor (PFET). In another embodiment, an N-channel field-effect transistor NPFET) is produced by doping the second semiconductor layer 208 with elements from group V of the periodic table (e.g., phosphorus, antimony, or arsenic).

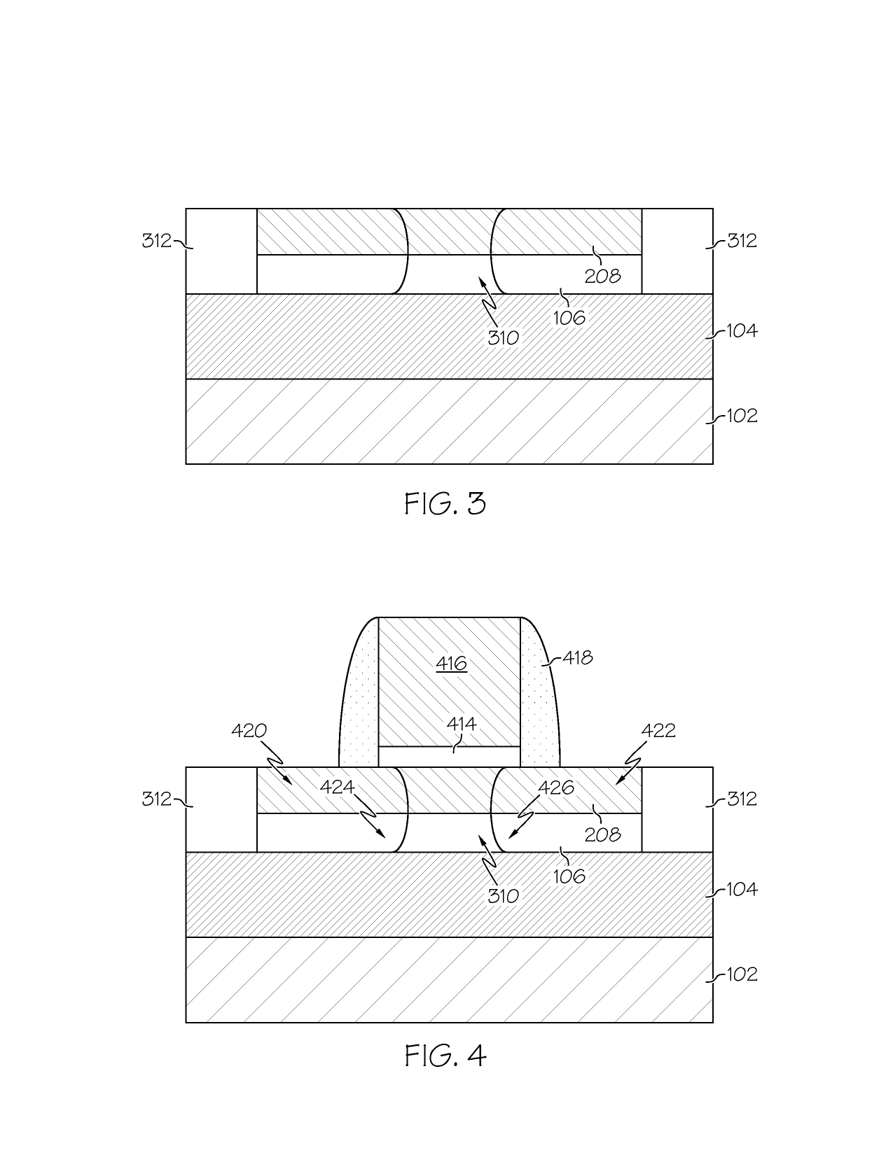

As shown in FIG. 3, an active area (channel region) 310 for the transistor is then defined within the ETSOI layer 106 through pad-film deposition, photolithography, and reactive-ion etching (RIE). For example, a pad oxide having a thickness of 2 nm to 10 nm is formed in an oxidation furnace, and a pad nitride is deposited over the pad oxide using low-pressure chemical vapor deposition (LPCVD) or rapid-thermal chemical vapor deposition (RTCVD). Photolithography and a nitride-oxide-silicon RIE are then performed to define the active area.

Next, the active area 310 is isolated, such as through shallow trench isolation (STI). In this embodiment, STI is obtained through deposition of an STI oxide, densification anneals, and chemical-mechanical polishing (CMP) that stops on the pad nitride. This forms an STI region 312 above the BOX layer 104 that is continuous around the active area 310. The pad nitride, along with any STI oxide remaining on the pad nitride, and the pad oxide are then removed (e.g., through wet etching using hot phosphoric acid and HF).

As shown in FIG. 4, a dummy (or replacement) gate dielectric 414 and gate conductor 416 are formed on the active area 310. In this embodiment, the dummy gate dielectric 414 and gate conductor 416 are formed of oxide, polysilicon, amorphous silicon, nitride, or a combination thereof. This dummy gate stack 414 and 416 acts as a place holder for the actual gate stack that is later formed after recessed channel formation. Additionally, a gate spacer 418 formed of a dielectric material (such as silicon oxide, silicon nitride, silicon oxynitride, or a combination of these) is formed on the sidewalls of the dummy gate stack 414 and 416. In this embodiment, the dielectric layer is formed and then reactive-ion etching is used to remove the dielectric material except from the sidewalls of the dummy gate stack 414 and 416. Alternatively, the gate spacer layer can be allowed to also remain on top of the dummy gate stack 414 and 416. In one embodiment, after the gate spacer 418 is formed, an additional epitaxial growth is performed on the second semiconductor layer 208 to further increase source/drain thickness, and therefore lower source/drain resistance.

The second semiconductor layer 208 provides the raised source and drain regions of the semiconductor device. In the illustrated embodiment in which the second semiconductor layer 208 is formed undoped, deep source/drain and extension implantation is performed using the gate spacer 418 to align the implantation. In this embodiment, photolithography is used to selectively define NFET and PFET areas for deep source/drain and extension implants, and then ions are implanted. N-type species are implanted for NFETs, while P-type species are implanted for PFETs. A thermal anneal is then performed to activate and diffuse the implanted ions so as to form the raised source/drain regions 420 and 422 and the source/drain extensions 424 and 426, such as through a spike rapid-thermal anneal (RTA). In another embodiment in which the second semiconductor layer 208 is doped, annealing (such as rapid thermal annealing, furnace annealing, flash lamp annealing, laser annealing, or any suitable combination thereof) can be used to drive the dopants from the second semiconductor layer 208 into the ETSOI layer 106 to provide the extension regions 424 and 426.

In the illustrated embodiment, for an NFET, the source/drain regions 420 and 422 can be heavily doped with an N-type dopant, the source/drain extension regions 424 and 426 can be lightly doped with the same or a different N-type dopant, and the halo regions can be doped with a P-type dopant. Conversely, for a PFET, the source/drain regions 420 and 422 can be heavily doped with a P-type dopant, the source/drain extension regions 424 and 426 can be lightly doped with the same or a different P-type dopant, and the halo regions can be doped with an N-type dopant.

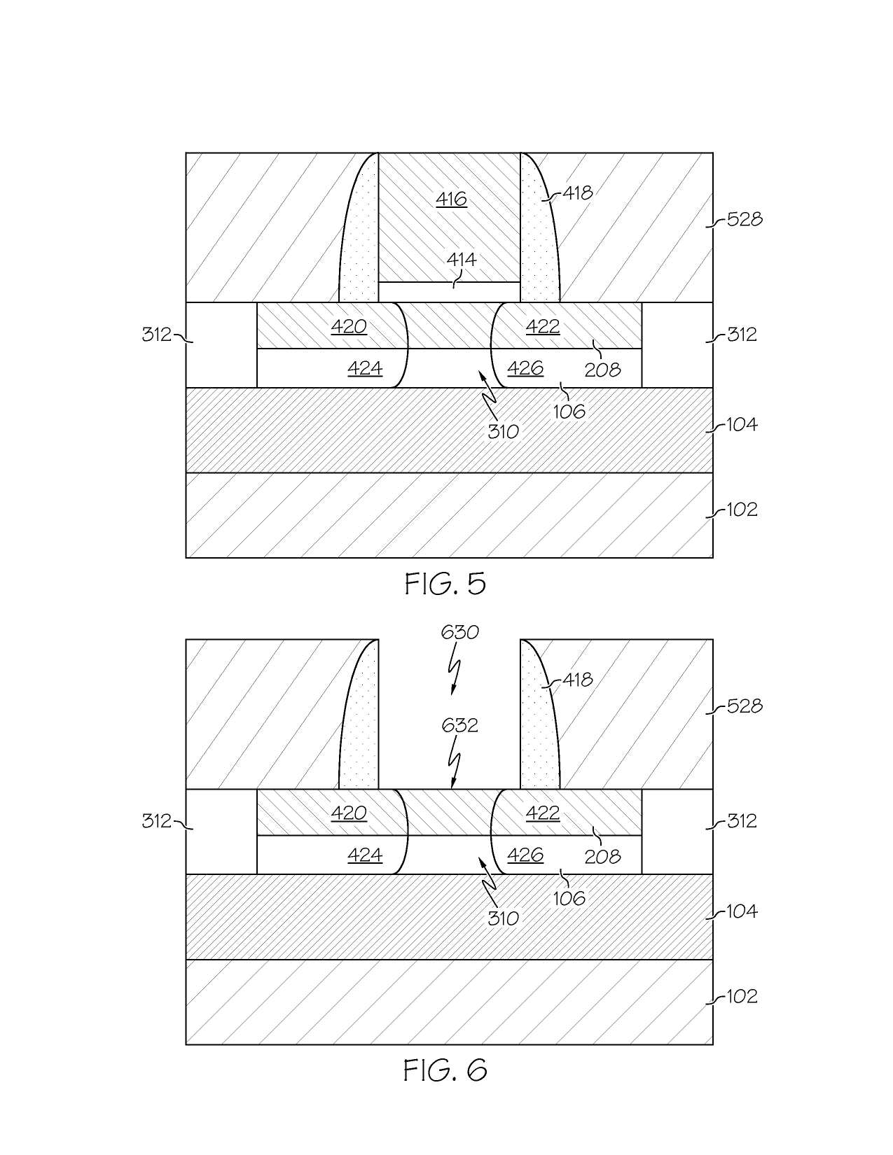

After the source/drain regions 420 and 422 have been formed, a dielectric layer 528 (e.g., an oxide layer) is then formed over the entire structure, as shown in FIG. 5. This dielectric layer 528 is then etched down to the level of the top surface of the dummy gate stack 414 and 416. Then, the dummy gate stack 414 and 416 is removed via selective etching or another technique to form a gate cavity 630 that exposes a portion 632 of the second semiconductor layer 208, as shown in FIG. 6.

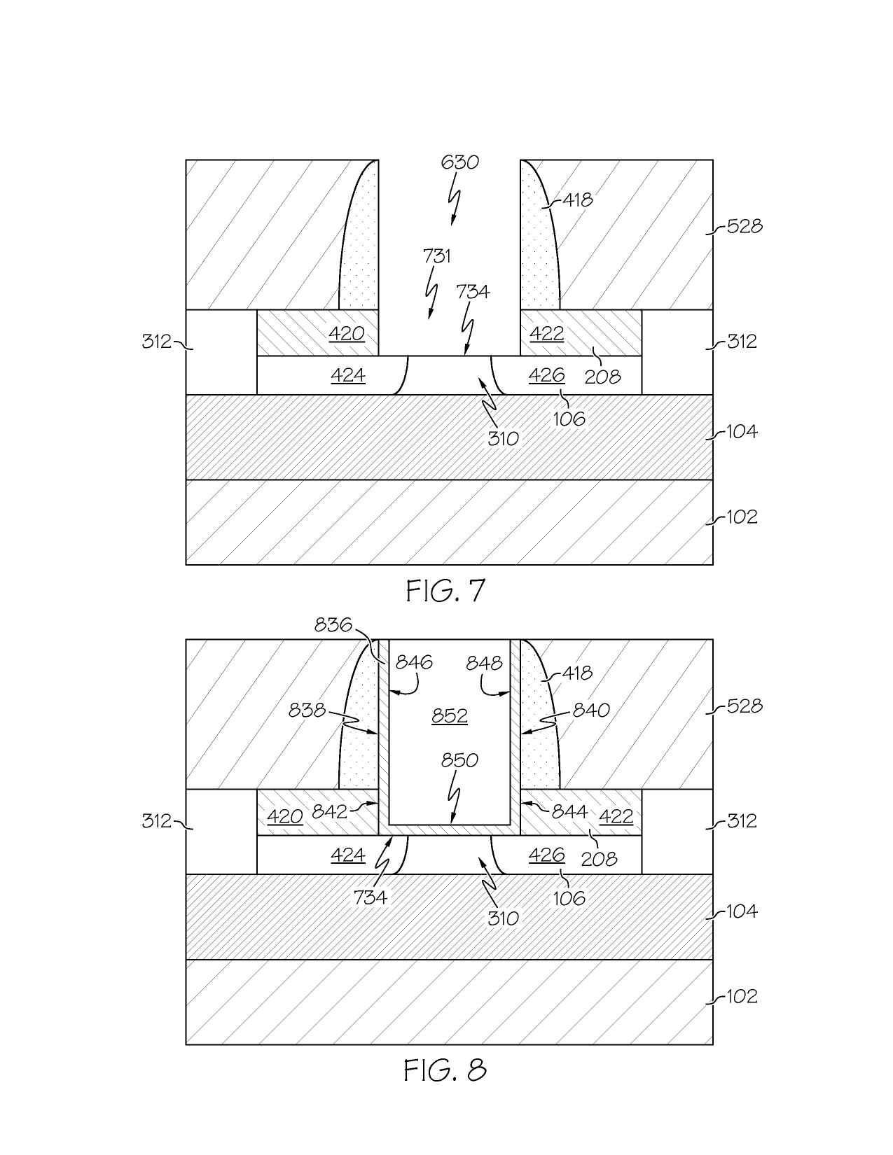

The second semiconductor layer 208 is then selectively removed with respect to the ETSOI layer 106 to deepen the gate cavity, as shown in FIG. 7. In the illustrated embodiment, the portion 632 of the second semiconductor layer 208 below the cavity is selectively etched so as to stop at the ETSOI layer 106 and leave additional gate cavity area 731. This exposes a portion 734 of the underlying ETSOI layer 106 under the gate cavity 630 and creates vertical sidewalls in the second semiconductor layer 208, as shown in FIG. 7. After the second semiconductor layer 208 has been selectively removed, a high-k dielectric layer is blanket deposed, for example by CVD (chemical vapor deposition), PECVD (plasma enhanced chemical vapor deposition), or ALD (Atomic layer deposition). This high-k dielectric layer is then selectively etched using a process such as RIE (reactive ion etching) to form a high-k gate dielectric 836 on the bottom and vertical sidewalls of the gate cavity, as shown in FIG. 8.

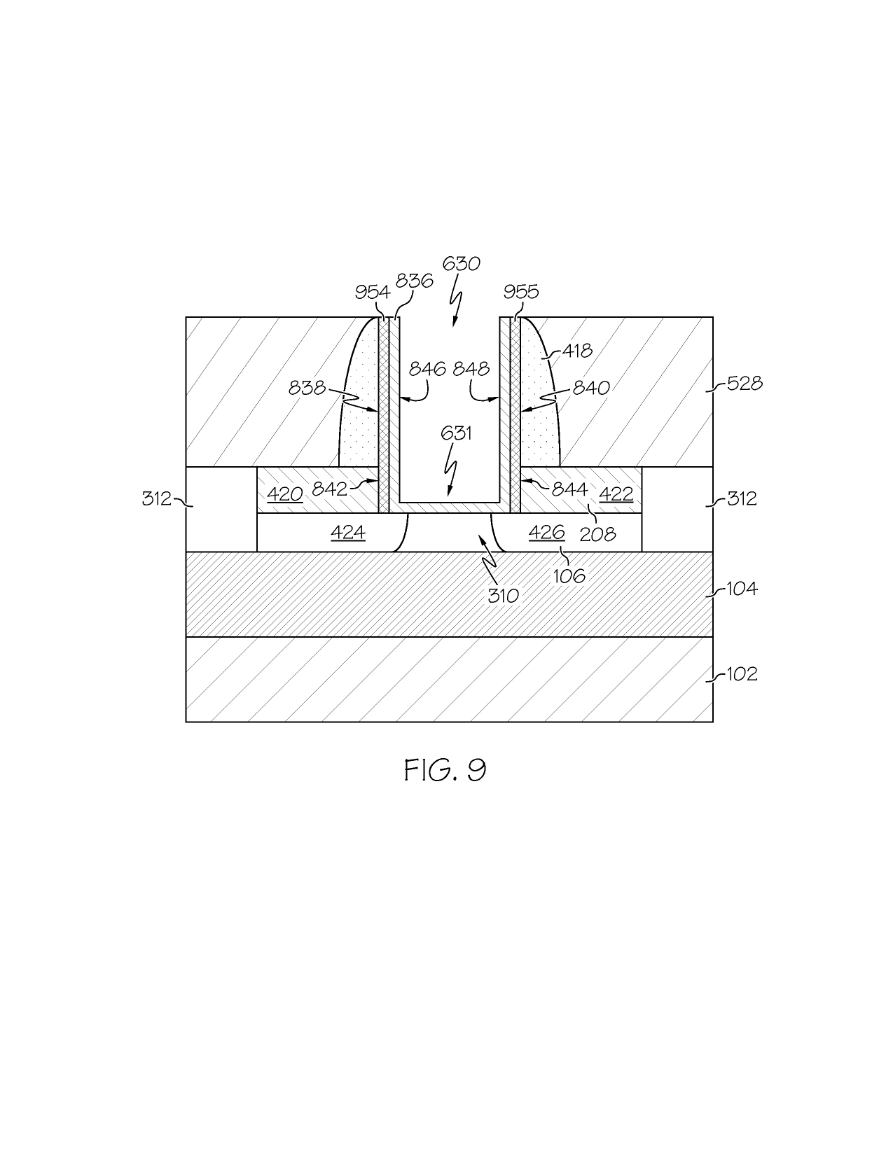

In an alternative embodiment shown in FIG. 9, an additional dielectric layer 954 and 955 of a conventional dielectric material (such as silicon oxide, silicon nitride, silicon oxynitride, or a combination of these) is formed on the vertical surfaces of the gate cavity 630 and 631. The addition of this additional dielectric layer 954 and 955 reduces the parasitic capacitance between the gate and source/drain regions. After this additional dielectric layer 954 and 955 has been formed, the high-k gate dielectric 836 is then formed in the gate cavity as described above. Therefore, in the alternative embodiment of FIG. 9, the additional dielectric layer 954 and 955 is situated between the vertical sidewalls 838 and 840 of the gate spacer 418 and the vertical sidewalls of the high-k gate dielectric 836.

After the high-k gate dielectric 836 has been formed, a gate conductor material is then deposited and etched to form a gate conductor 852 in the cavity, as shown in FIG. 8. The gate conductor 852 fills the remaining portion of the gate cavity. In the illustrated embodiment, the gate conductor 852 is a metal layer comprising a conductive refractory metal nitride, such as TaN (tantalum nitride), TiN (titanium nitride), WN (tungsten nitride), TiAlN (titanium aluminum nitride), TaCN (triazacyclononane), or an alloy thereof. In some embodiments, a gate polysilicon is deposited on the gate conductor layer 852, such as through LPCVD or silicon sputtering.

As shown in FIG.8, the raised source/drain regions 420 and 422 are located on both sides of the gate stack 836 and 852 in the second semiconductor layer, and below the gate spacer 418 such that a portion of the raised source/drain regions 420 and 422 abuts a bottom portion of the gate spacer 418. The source/drain extension regions 424 and 426 extend under the gate stack 836 and 852 and abut a bottom portion of the high-k gate dielectric 836. The channel region 310 is located in the ETSOI layer 106 between the source/drain extension regions 424 and 426.

After the gate conductor 852 has been formed, the dielectric layer 528 is removed using a conventional process. Next, silicide areas are formed for contacts. In one embodiment, a metal is deposited on top of the source/drain regions 420 and 422, an anneal is performed to form silicide, and then the metal is selectively removed while leaving the silicide untouched (e.g., through an aqua regia wet etch). For example, the metal is nickel, cobalt, titanium, platinum, or a combination thereof. Conventional fabrication steps are then performed to form the remainder of the integrated circuit that includes this transistor.

The principles of the present invention are also applicable to finFETs. After fin formation, an epitaxial layer is grown on the sidewalls of the fin (e.g., with the fin being silicon and the epitaxial layer being SiGe). A dummy gate is formed and the source/drain regions are formed in the epitaxial layer and the ETSOI/fin layer. The dummy gate is the removed to expose the epitaxial layer in the channel region. The exposed epitaxial layer is then selectively removed with respect to the silicon fin layer.

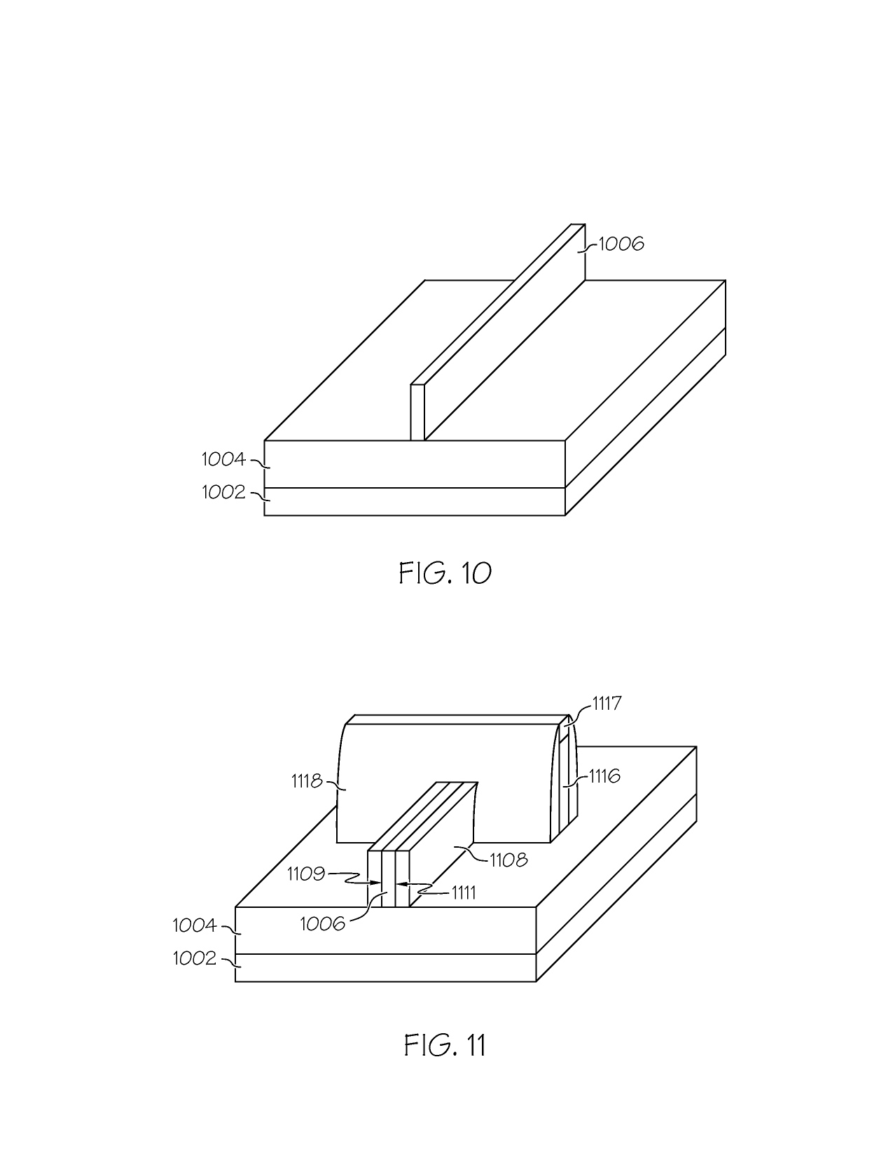

FIGS. 10 to 14 illustrate a process for forming a finFET transistor with a recessed channel and raised source/drain regions according to a further embodiment of the present invention. An initial structure is formed with a substrate layer 1002, an overlying dielectric layer 1004 (such as a BOX layer), and a fin structure 1006 atop the dielectric layer 1004. In the illustrated embodiment, the initial structure is formed from an SOI substrate, with the top semiconductor layer (or “SOI layer”) of the SOI forming the fin structure 1006. The substrate 1002 and the SOI layer are electrically isolated from one another by the dielectric layer 1004.

For example, the SOI layer and the substrate layer 1002 comprise at least one of Si, Ge alloys, SiGe, GaAs, InAs, InP, SiCGe, SiC, and other III/V or II/VI compound semiconductors. The SOI layer and substrate layer 1002 can be made of the same or different materials. The dielectric layer 1004 is a crystalline or non-crystalline oxide, nitride, oxynitride, or any other insulating material. The SOI substrate can be formed utilizing a layer transfer process including a bonding step, or an implantation process such as SIMOX (Separation by IMplantation of OXygen).

In the illustrated embodiment, photolithography and etching are used to form the initial structure that is depicted in FIG. 10. Alternatively, the fin structure 1006 can be formed by the spacer imaging transfer technique. After the fin structure 1006 is formed, an additional semiconductor layer 1108 is grown on the sidewalls 1109 and 1111 of the fin structure, as shown in FIG. 11. The additional semiconductor layer 1108 Is used for the raised source/drain regions of the finFET device. In this embodiment, the additional semiconductor material 1108 is formed using epitaxial growth, and can be formed undoped or doped with either P-type or N-type dopants. Silicon sources for epitaxial growth include silicon tetrachloride, dichlorosilane (SiH2Cl2), and silane (SiH4).

In one embodiment, the additional semiconductor material 1108 is formed by selective-epitaxial growth of SiGe on the exposed sidewalls 1109 and 1111 of the fin structure 1006. The Ge content of the epitaxially grown SiGe ranges from 5% to 70% (by atomic weight). In another embodiment, the Ge content of the epitaxially grown SiGe ranges from 10% to 45%. The epitaxially grown SiGe of the illustrated embodiment produces a compressive strain in the portion of the fin structure 1006 in which the channel of a semiconductor device is subsequently formed.

P-type finFET devices are produced by doping the additional semiconductor material 1108 with elements from group III of the periodic table (e.g., boron, aluminum, gallium, or indium). As an example, the dopant may be boron in a concentration ranging from 1×10¹⁹ atoms/cm³ to 2×10²¹ atoms/cm³. In the illustrated embodiment, the additional semiconductor material 1108 is composed of SiGe and is doped with boron to provide the raised source/drain regions of a P-channel finFET.

In another embodiment, the additional semiconductor material 1108 is composed of epitaxially grown Si:C (carbon doped silicon). The carbon (C) content of the epitaxial grown Si:C ranges from 0.5% to 10% (by atomic weight). In another embodiment, the carbon (C) content of the epitaxial grown Si:C ranges from 1% to 2%. In one embodiment, the epitaxial grown Si:C produces a tensile strain in the portion of the fin structure 1006 in which the channel of the finFET is subsequently formed.

In this embodiment, the additional semiconductor material 1108 is doped with a second conductivity type dopant during the epitaxial growth process. N-channel finFET devices are produced by doping the additional semiconductor material 1108 with elements from group V of the periodic table (e.g., phosphorus, antimony, or arsenic).

As shown in FIG. 11, a dummy gate 1116 is formed on the fin structure 1006. The dummy gate 1116 is formed using oxide, polysilicon, amorphous silicon, nitride, or a combination thereof. This dummy gate 1116 acts as a place holder for the gate stack, as discussed above. A hard mask 1117 is formed on top of the dummy gate 1116. The hard mask 1117 comprises a dielectric material such as a nitride, oxide, oxynitride material, and/or any other suitable dielectric layer. The dielectric hard mask 1117 can be a single layer of dielectric material or multiple layers of dielectric materials, and can be formed by a deposition process such as chemical vapor deposition (CVD) and/or atomic layer deposition (ALD). Alternatively, the hard mask 1117 can be grown, such as through thermal oxidation or thermal nitridation.

In the illustrated embodiment, a gate (dielectric) spacer 1118 is formed by depositing a conformal layer of dielectric material (such as an oxide, nitride, or oxynitride) and then performing an anisotropic etch (such as a reactive ion etch). After the gate spacer 1118 has been formed, diffusion/annealing is performed to drive dopants from the additional semiconductor layer 1006 into the fin structure 1006 to form source/drain extension regions. In an embodiment in which the additional semiconductor layer 1006 is undoped, source/drain and extension implantation is performed using the gate spacer 1118 to align the implantation. In this embodiment, photolithography is used to selectively define NFET and PFET areas for deep source/drain and extension implants, and then ions are implanted. N-type species are implanted for NFETs, while p-type species are implanted for PFETs. A thermal anneal is then performed to activate and diffuse the ions, such as through a spike rapid-thermal anneal (RTA).

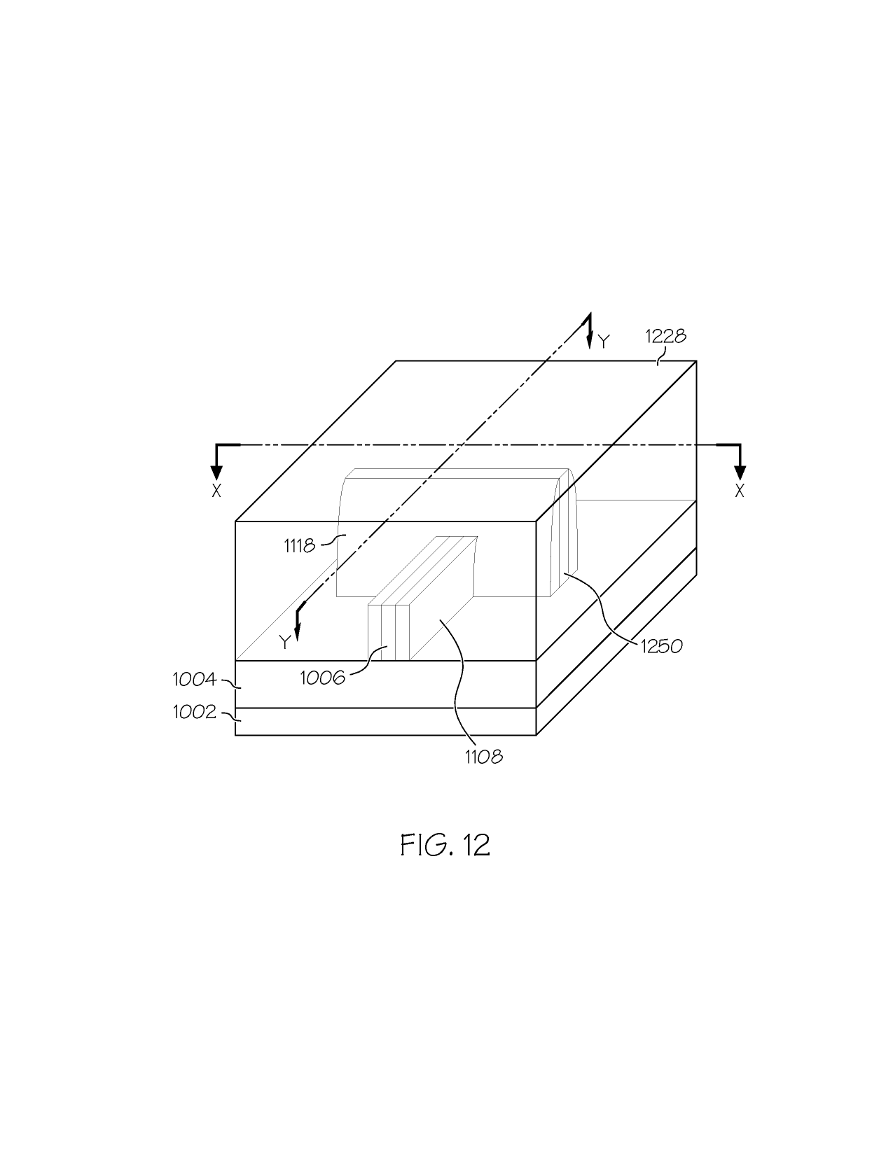

After the source/drain and extension regions have been formed, a dielectric layer 1228 (e.g., an oxide layer) is then formed over the dielectric layer 1004, the fin structure 1006, the additional semiconductor layer 1108, the dummy gate 1116, and the hard mask 1117, as shown in FIG. 12. This dielectric layer 1228 is etched down to the upper surface of the hard mask 1117 (or the dummy gate 1116 in embodiments in which a hard mask 1117 is not used). Then the dummy gate 1116 and hard mask 1117 are removed via selective etching or another conventional technique, as discussed above. This forms a gate cavity 1230 that exposes a portion of the additional semiconductor layer 1108 and the fin structure 1006, as shown in FIG. 12.

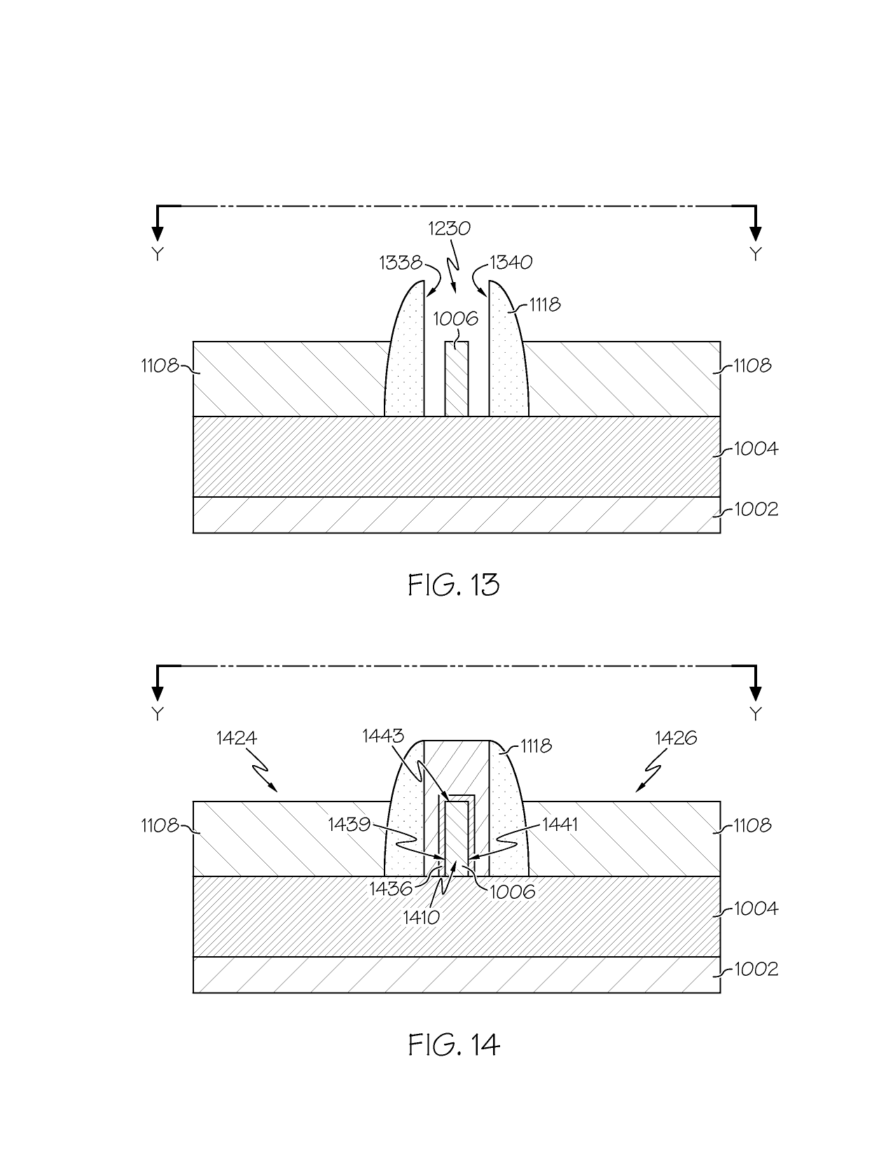

The exposed portion of the additional semiconductor layer 1108 is then selectively etched with respect to the fin structure 1006, as shown in FIG. 13.

This etching extends the gate cavity 1230 down to the dielectric layer 1104, so as to separate the sidewall 1338 and 1340 of the gate spacer 1118 from the exposed portion of the fin structure 1006. After the additional semiconductor layer 1108 has been selectively etched, a layer of a high-k dielectric material is blanket deposited (for example, by CVD, PECVD, or ALD) and then selectively etched using a process such as RIE to form a high-k dielectric spacer 1436 only on the fin structure sidewalls 1109, 1111, 1439, and 1441 and upper horizontal surface 1443, as shown in FIG. 14.

After the high-k dielectric spacer 1436 has been formed, a gate conductor material is then deposited over the structure, lithographically patterned, and etched to form a gate conductor 1452, as shown in FIG. 14. The gate conductor 1452 fills the remaining portion of the gate cavity 1230. The gate conductor 1452 of this embodiment is a metal gate layer comprising a conductive refractory metal nitride, such as TaN, TiN, WN, TiAIN, TaCN, or an alloy thereof.

The resulting structure has a channel region 1410 formed by the thin fin structure 1006 surrounded by the high-k dielectric spacer 1436 and gate conductor 1452, as shown in FIG. 14. The extension regions 1424 and 1426 are formed by the fin structure 1006 surrounded by the additional semiconductor layer 1108, which lowers the extension resistance. In one embodiment, the fin structure comprises Si, the additional semiconductor layer 1108 comprises SiGe, and the extension regions 1424 and 1426 comprise SiGe/Si/SiGe. Doped epitaxial source/drain regions (in additional semiconductor layer 1108) are in direct contact with the gate spacer 1118. Extension regions 1424 and 1426 extend from the doped epitaxial source/drain regions into the gate spacer 1118. Conventional fabrication steps are then performed to form the remainder of the integrated circuit that includes this transistor.

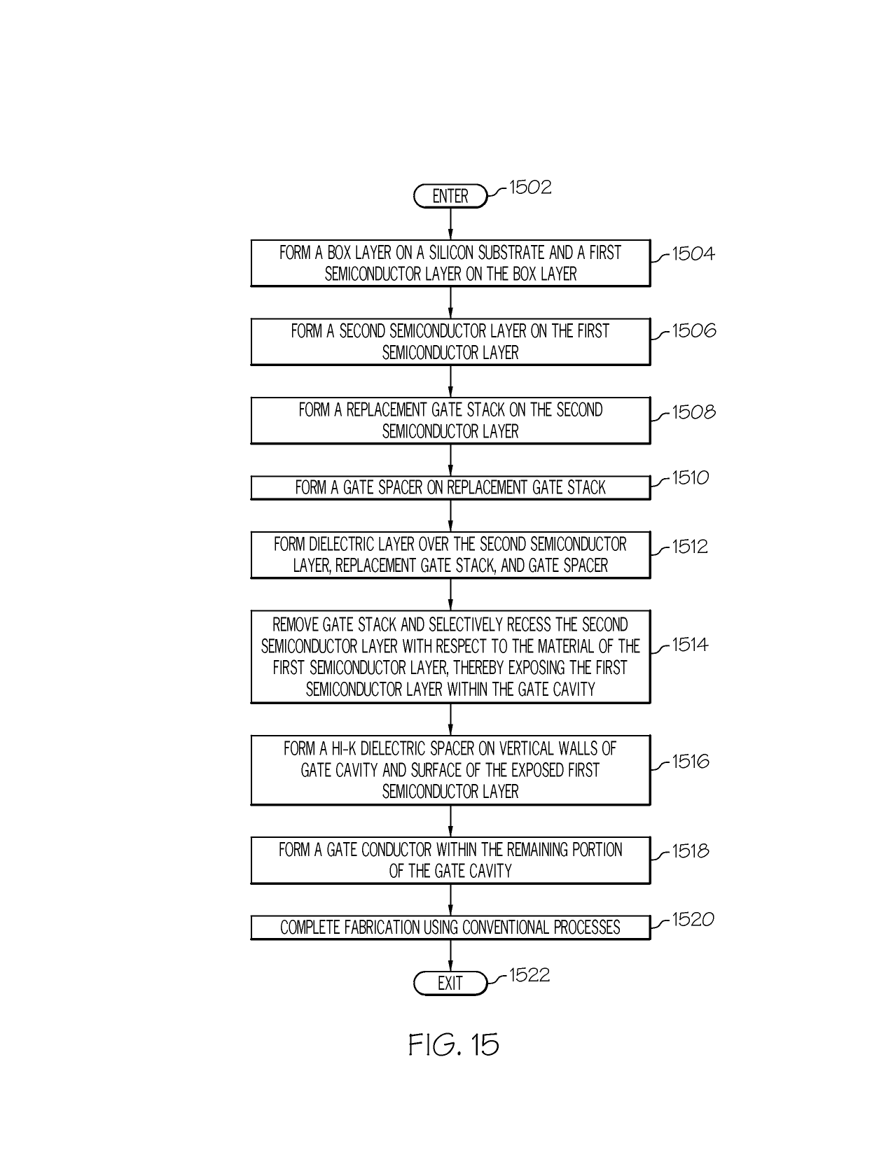

FIG. 15 is an operational flow diagram illustrating a process for forming an ETSOI transistor with a recessed channel and raised source/drain regions according to one embodiment of the present invention. A BOX layer 104 is formed on a silicon substrate 102, and a first semiconductor layer 106 (e.g., ETSOI layer) is formed on the BOX layer 104, step 1504. A second semiconductor layer 208 is formed on the first semiconductor 106, at step 1506. A dummy gate stack 414 and 416 is formed on the second semiconductor layer 208, at step 1508.

A gate spacer 418 is then formed on the dummy gate stack 414 and 416, at step 1510. A dielectric layer 528 is formed over the second semiconductor layer 208, the dummy gate 416 and 418, and the gate spacer 418, at step 512. The dummy gate stack 414 and 416 is removed and the second semiconductor layer 208 within the gate cavity 630 is selectively etched with respect to the first semiconductor layer 106, at step 1514. This exposes a portion of the first semiconductor layer 106 below the gate cavity 630. A high-k dielectric spacer 836 is then formed on the walls of the gate cavity 630, at step 1516. A gate conductor 852 is then formed in the remaining portion of the gate cavity 630, at step 1518. Conventional steps are then performed to complete the fabrication process, at step 1520.

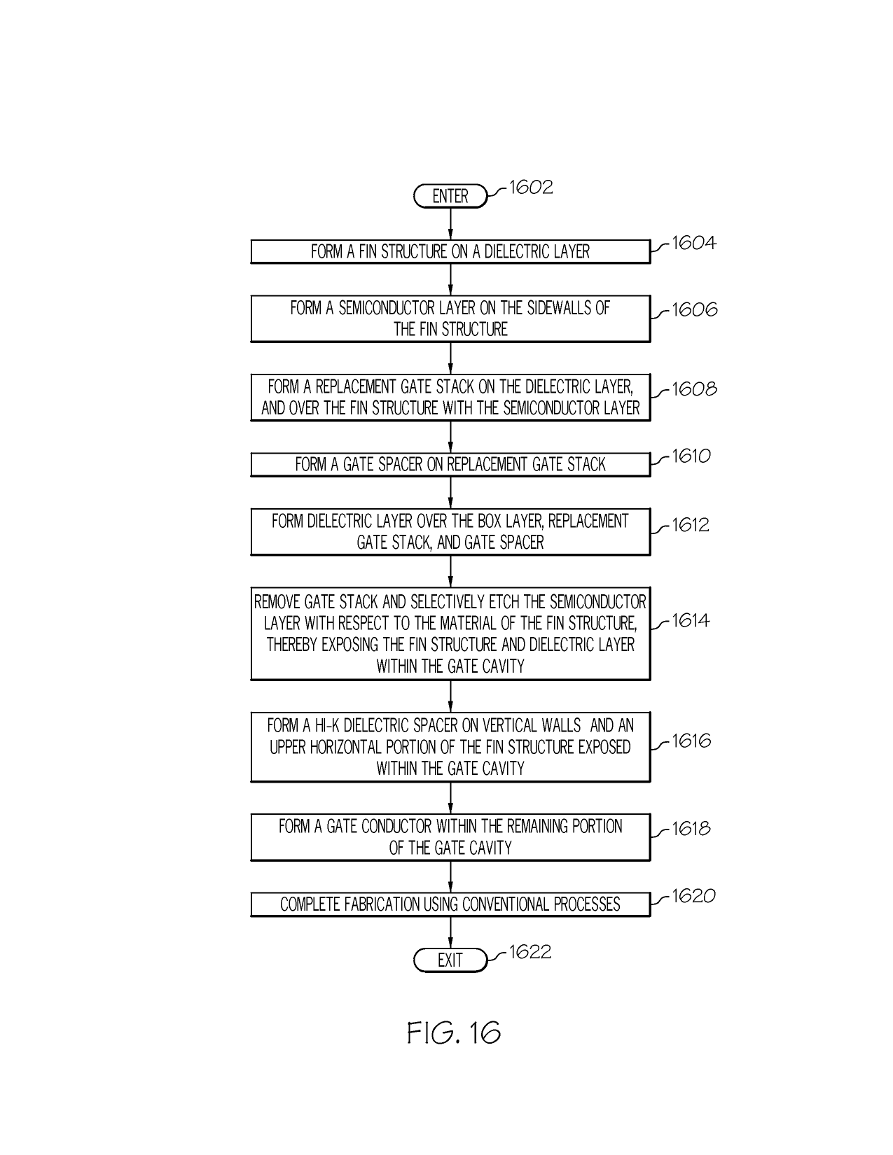

FIG. 16 is an operational flow diagram illustrating a process for forming a finFET transistor with a recessed channel and raised source/drain regions according to one embodiment of the present invention. A fin structure 1006 is formed on a dielectric layer 1004, at step 1604. A semiconductor layer 1108 is formed on the sidewalls of the fin structure 1006, at step 1606. A dummy gate 1116 (and an optional hard mask 1117) is formed on the dielectric layer 1004 and over the fin structure 1006 comprising the semiconductor material 1108, at step 1608.

A gate spacer 1118 is then formed on the dummy gate 1116, at step 1610. A dielectric layer 1228 is formed over the dielectric layer 1004, the dummy gate 1116, and gate spacer 1118, at step 1612. The dummy gate 1116 is removed and the semiconductor layer 1108 within the gate cavity 1230 is selectively etched with respect to the fin structure 1006, at step 1614. This exposes a portion of the fin structure 1006 in the gate cavity 1230. A high-k dielectric spacer 1436 is then formed on vertical walls and the upper horizontal portion of the exposed fin structure 1006, at step 1616. A gate conductor 1452 is then formed in the remaining portion of the gate cavity 1230, at step 1618. Conventional steps are then performed to complete the fabrication process, at step 1620.

It should be noted that some features of the present invention may be used in an embodiment thereof without use of other features of the present invention. As such, the foregoing description should be considered as merely illustrative of the principles, teachings, examples, and exemplary embodiments of the present invention, and not a limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above are used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for fabricating a transistor, the method comprising:
forming a second semiconductor layer on a first semiconductor layer;
forming a dummy gate structure on the second semiconductor layer;
after forming the dummy gate structure, forming a gate spacer on vertical sidewalls of the dummy gate structure;
after forming the gate spacer, removing the dummy gate structure, the removing forming a cavity;
removing the second semiconductor layer beneath the cavity, the removing exposing a first portion of the first semiconductor layer and creating vertical sidewalls of the second semiconductor layer;
forming a gate dielectric comprising a first portion located on the first portion of the first semiconductor layer and a second portion adjacent to the vertical sidewalls of the second semiconductor layer and vertical sidewalls of the gate spacer;
forming a gate conductor on the first portion of the gate dielectric and abutting the second portion of the gate dielectric; and
forming raised source/drain regions in the second semiconductor layer, at least part of the raised source/drain regions being located below the gate spacer.

2. The method of claim 1, further comprising:
providing a silicon substrate;
forming a buried oxide layer on the substrate; and forming the first semiconductor layer on the buried oxide layer, the first semiconductor layer comprising silicon and having a thickness of less than about 10 nanometers.

3. The method of claim 2, wherein the gate dielectric comprises a high-k dielectric material.

4. The method of claim 3, further comprising forming a dielectric spacer between the second portion of the gate dielectric and the vertical sidewalls of the second semiconductor layer and the gate spacer.

5. The method of claim 3, wherein the second portion of the gate dielectric is located on the vertical sidewalls of the second semiconductor layer and the gate spacer.

6. The method of claim 3, further comprising forming source/drain extension regions in the first semiconductor layer below the raised source/drain regions.

7. The method of claim 3, wherein forming the second semiconductor layer comprises epitaxially growing a silicon-germanium layer on the first semiconductor layer.

8. A method for fabricating a fin-field-effect-transistor, the method comprising:
providing a fin structure atop a dielectric layer;
forming a semiconductor material on sidewalls of the fin structure;
forming a dummy gate structure on the fin structure and the semiconductor material;
after forming the dummy gate structure, forming a gate spacer on vertical sidewalls of the dummy gate structure;
after forming the gate spacer, removing the dummy gate structure, wherein the removing forms a cavity and an exposed portion of the fin structure in the cavity;
after the cavity is formed, removing the semiconductor layer from sidewalls of portion of the fin structure;
forming a dielectric spacer on the exposed portion of the fin structure; and
forming a gate conductor within the cavity and over the dielectric spacer.

9. The method of claim 8, wherein the dielectric spacer is formed on vertical sidewalls of the exposed portion of the fin structure and on an upper horizontal surface of the exposed portion of the fin structure.

10. The method of claim 8, where forming the semiconductor material on sidewalls of the fin structure comprises:
epitaxially growing the semiconductor material the sidewalls of the fin structure.

11. The method of claim 8, further comprising:
forming source/drain regions within the semiconductor material.

12. The method of claim 8, wherein the dielectric spacer comprises a high-k dielectric material.
